(19) United States
(12) Patent Application Publication
(10) Pub. No.: US 2026/0011615 A1
(43) Pub. Date: Jan. 8, 2026

(54) ELECTRONIC DEVICE

(71) Applicant: InnoLux Corporation, Miao-Li County (TW)

(72) Inventors: Jeng-Nan LIN, Miao-Li County (TW); Ju-Li Wang, Miao-Li County (TW); Te-Hsun Lin, Miao-Li County (TW); Cheng-Tse Tsai, Miao-Li County (TW)

(73) Assignee: InnoLux Corporation, Miao-Li County (TW)

(21) Appl. No.: 19/232,857

(22) Filed: Jun. 9, 2025

Related U.S. Application Data
(60) Provisional application No. 63/667,813, filed on Jul. 5, 2024.

(30) Foreign Application Priority Data
Dec. 19, 2024 (CN) 202411876786.3

(51) Int. Cl. H01L 23/31; H01L 23/00; H01L 23/34; H01L 23/498

(52) U.S. Cl. CPC H01L 23/3107; H01L 23/34; H01L 23/49822; H01L 23/562; H01L 23/49811; H01L 24/16; H01L 2224/16227

(57) ABSTRACT

An electronic device includes a circuit structure, a first electronic unit and an encapsulation layer. The first electronic unit is disposed on the circuit structure. The encapsulation layer surrounds the first electronic unit. The circuit structure includes at least one first insulating layer and at least one second insulating layer. The at least one first insulating layer is disposed between the first electronic unit and the at least one second insulating layer. A stiffness of the at least one first insulating layer is less than a stiffness of the at least one second insulating layer.

### CROSS REFERENCE TO RELATED APPLICATION

This application claims the benefit of U.S. Provisional Application No. 63/667,813, filed on Jul. 5, 2024. The content of the application is incorporated herein by reference.

### BACKGROUND OF THE DISCLOSURE

### 1. Field of the Disclosure

The present disclosure relates to an electronic device, and more particularly, to an electronic device which is beneficial to improve both the input/output density and the supportability thereof.

### 2. Description of the Prior Art

With the trend of miniaturization of electronic devices, the arrangement of electronic elements in electronic products becomes denser. In order to increase the input/output (I/O) density, a dielectric material with a thinner thickness may be selected as a dielectric layer of a redistribution layer (RDL). However, the strength or the stiffness of the redistribution layer may be reduced, which affects the supportability of the electronic device. For example, the probability of warpage increases, or the yield of the electronic device decreases.

### SUMMARY OF THE DISCLOSURE

According to an embodiment of the present disclosure, an electronic device includes a circuit structure, a first electronic unit and an encapsulation layer. The first electronic unit is disposed on the circuit structure. The encapsulation layer surrounds the first electronic unit. The circuit structure includes at least one first insulating layer and at least one second insulating layer. The at least one first insulating layer is disposed between the first electronic unit and the at least one second insulating layer. A stiffness of the at least one first insulating layer is less than a stiffness of the at least one second insulating layer.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic cross-sectional view showing an electronic device according to an embodiment of the present disclosure.

FIG. 2 to FIG. 3 are schematic cross-sectional views showing a method for manufacturing the electronic device shown in FIG. 1.

FIG. 4 is a schematic cross-sectional view showing an electronic device according to another embodiment of the present disclosure.

FIG. 5 to FIG. 6 are schematic cross-sectional views showing a method for manufacturing the electronic device shown in FIG. 4.

FIG. 7 is a schematic cross-sectional view showing an electronic device according to yet another embodiment of the present disclosure.

FIG. 8 to FIG. 9 are schematic cross-sectional views showing a method for manufacturing the electronic device shown in FIG. 7.

FIG. 10 is a schematic cross-sectional view showing an electronic device according to yet another embodiment of the present disclosure.

FIG. 11, FIG. 12 and FIG. 13 are schematic cross-sectional views showing a method for manufacturing the electronic device shown in FIG. 10.

FIG. 14 is a schematic cross-sectional view showing an electronic device according to yet another embodiment of the present disclosure.

### DETAILED DESCRIPTION

The present disclosure may be understood by reference to the following detailed description, taken in conjunction with the drawings as described below. Wherever possible, the same or similar parts in the drawings and descriptions are represented by the same reference numeral.

Certain terms are used throughout the description and following claims to refer to particular components. As one skilled in the art will understand, electronic equipment manufacturers may refer to a component by different names. This document does not intend to distinguish between components that differ in name but not function. In the following description and in the claims, the terms “include/comprise” and “have” are used in an open-ended fashion, and thus should be interpreted to mean “include, but not limited to . . . ”.

In the present disclosure, the directional terms, such as “on/up/above”, “down/below”, “front”, “rear/back”, “left”, “right”, etc., are only directions referring to the drawings. Therefore, the directional terms are used for explaining and not used for limiting the present disclosure. Regarding the drawings, the drawings show the general characteristics of methods, structures, and/or materials used in specific embodiments. However, the drawings should not be construed as defining or limiting the scope or properties encompassed by these embodiments. For example, for clarity, the relative size, thickness, and position of each layer, each area, and/or each structure may be reduced or enlarged.

In the present disclosure, when a structure (or layer, or component, or substrate) is described as located on/above another structure (or layer, or component, or substrate), it may refer that the two structures are adjacent and directly connected to each other, or the two structures are adjacent and indirectly connected to each other. The two structures being indirectly connected to each other may refer that at least one intervening structure (or intervening layer, or intervening component, or intervening substrate, or intervening interval) exists between the two structures, a lower surface of one of the two structure is adjacent or directly connected to an upper surface of the intervening structure, and an upper surface of the other of the two structures is adjacent or directly connected to a lower surface of the intervening structure. The intervening structure may be a single-layer or multi-layer physical structure or a non-physical structure, and the present disclosure is not limited thereto. In the present disclosure, when a certain structure is disposed “on/above” other structures, it may refer that the certain structure is “directly” disposed on/above the other structures, or the certain structure is “indirectly” disposed on/above the other structures, i.e., at least one structure is disposed between the certain structure and the other structures.

In the present disclosure, the term “connection” may include physical connection or electrical connection, and may include direct contact or indirect contact.

In the present disclosure, the term “disposed on” is used for convenience of description and does not limit the process steps or sequence.

The terms “equal”, “identical/the same”, or “substantially/approximately” mentioned in this document generally mean being within 20% of a given value or range, or being within 10%, 5%, 3%, 2%, 1% or 0.5% of the given value or range.

Furthermore, any two values or directions used for comparison may have a certain error. If a first value is equal to a second value, it implies that there may be an error of about 10% between the first value and the second value; if a first direction is perpendicular or “substantially” perpendicular to a second direction, then an angle between the first direction and the second direction may be between 80 degrees to 100 degrees; if the first direction is parallel or “substantially” parallel to the second direction, an angle between the first direction and the second direction may be between 0 degree to 10 degrees.

Although ordinal numbers such as “first”, “second”, etc., may be used to describe elements in the description and the claims, it does not imply and represent that there have other previous ordinal number. The ordinal numbers do not represent the order of the elements or the manufacturing order of the elements. The ordinal numbers are only used for discriminate an element with a certain designation from another element with the same designation. The claims and the description may not use the same terms. Accordingly, a first element in the description may be a second element in the claims.

In addition, the term “a given range is from a first value to the second value” or “a given range falls within a range from a first value to a second value” refers that the given range includes the first value, the second value and other values therebetween.

In the present disclosure, “an element surrounds another element” may refer that in a cross-sectional view, the element at least contacts a side surface of the another element.

In the present disclosure, the process for manufacturing the electronic device may be, for example, applied to a wafer-level package (WLP) process or a panel-level package (PLP) process, and may be a chip first process or a chip last (i.e., RDL first) process.

Moreover, the electronic device of the present disclosure may be applied to a power module, a semiconductor package device, a display device, a light emitting device, a backlight device, an antenna device, a sensing device or a tiled device, but not limited thereto. The display device may be a non-self-luminous type display device or a self-luminous type display device. The antenna device may be a liquid-crystal-type antenna device or a non-liquid-crystal-type antenna device. The sensing device may be a device for sensing capacitance, light, thermal or ultrasonic, but not limited thereto. The electronic elements of the electronic device may include passive elements and active elements, such as capacitors, resistors, inductors, diodes and transistors. The diode may include a light emitting diode (LED) or a photodiode. The light emitting diode may include organic light emitting diode (OLED), mini LED, micro LED or quantum dot LED, but not limited thereto. The tiled device may exemplarily be a tiled display device or a tiled antenna device, but not limited thereto. Furthermore, the electronic devices may be foldable or flexible electronic devices. The electronic device may be any combination of aforementioned devices, but not limited thereto. Furthermore, a shape of the electronic device may be a rectangle, a circle, a polygon, a shape with curved edge or other suitable shapes. The electronic device may have peripheral systems, such as a driving system, a control system and a light system for supporting the display device, the antenna device, the wearable device (for example, including augmented reality (AR) device or virtual reality (VR) device), the vehicle-mounted device (for example, including car windshields) or the tiled device.

In the present disclosure, the redistribution layer structure may be electrically connected to each of the chips or electronic units through bonding elements, such as bumps, solder balls or pads. The redistribution layer structure may include at least one conductive layer and at least one insulating layer. The redistribution layer structure may be configured to redistribute circuits and/or further increase the circuit fan-out area, or different electronic elements may be electrically connected to each other through the redistribution layer structure. The method of forming the redistribution layer structure may include providing a stack of at least one insulating layer and at least one conductive layer, and may include processes such as photolithography, etching, surface treatment, laser and electroplating. The surface treatment may include roughening the surface of the insulating layer or the surface of the conductive layer to improve the bonding ability thereof, wherein the surface roughness of the insulating layer is different from the surface roughness of the conductive layer, or the surface roughness of the insulating layer is greater than the surface roughness of the conductive layer.

In the present disclosure, it should be understood that a depth, a thickness, a width or a height of each element, or a spaced distance or a distance between elements may be measured by an optical microscopy (OM), a scanning electron microscope (SEM), a film thickness profiler (a-step), an ellipsometer or other suitable methods. In some embodiments, a cross-sectional image including elements to be measured can be obtained by the SEM, and the depth, the thickness, the width or the height of each element, or the spaced distance or the distance between elements can be measured thereby.

In the present disclosure, the definition of roughness may be as follow. For example, a surface is observed by the SEM. When a distance difference of 0.15 μm to 1 μm is between the crest point and the trough point of the surface undulation on the surface to be observed, the surface to be observed is determined to be rough. In the present disclosure, the determination of roughness, for example, may use a SEM or a transmission electron microscope (TEM) to observe the surface undulation at a same appropriate magnification, and the undulation degree are compared by taking a unit length (such as 10 μm). Herein, “appropriate magnification” may refer that at least 10 undulating peaks can be seen on at least one surface under the field of view of the magnification.

In the present disclosure, Young's modulus can be, for example, measured by a universal testing machine. The measuring method may refer to the standard measuring method of the American Society for Testing and Materials (ASTM) E111.

It should be noted that the technical features in different embodiments described in the following can be replaced, recombined, or mixed with one another to constitute another embodiment without departing from the spirit of the present disclosure.

Unless otherwise defined, all terms (including technical and scientific terms) used herein have the same meaning as commonly understood by a person having ordinary skill in the art to which the present disclosure belongs. It can be understood that these terms, such as those defined in commonly used dictionaries, should be interpreted as having meanings consistent with the background or context of the related technology and the present disclosure, and should not be interpreted in an idealized or overly formal manner, unless otherwise specified in the disclosed embodiments.

In the present disclosure, the numbers of the first insulating layers, the second insulating layers, the first conductive layers, the second conductive layers, the holes, and the bonding elements in the electronic devices shown in the following drawings are only exemplary and are not limited thereby.

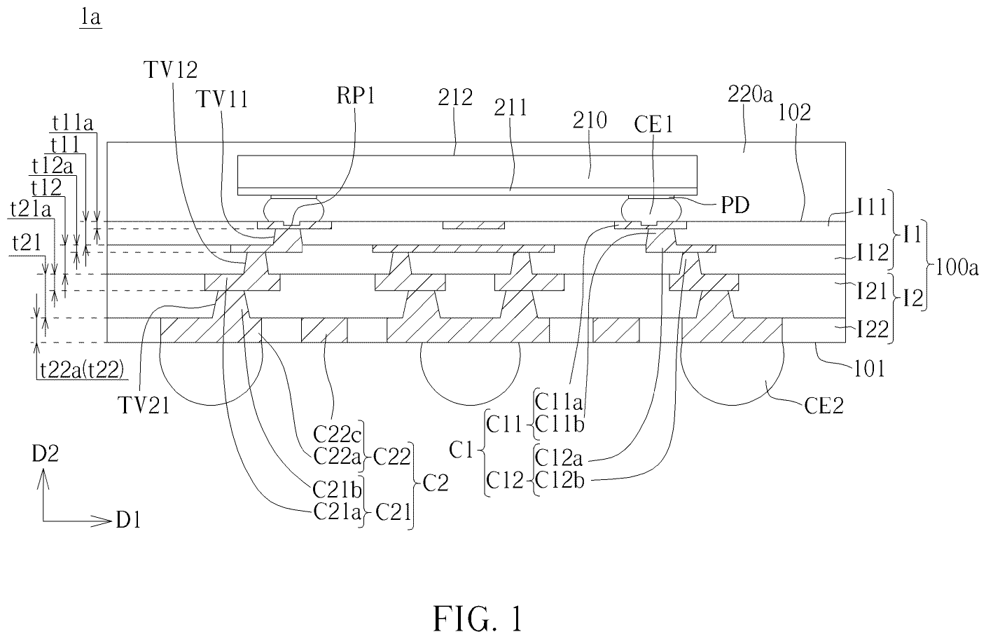

Please refer to FIG. 1, which is a schematic cross-sectional view showing an electronic device 1a according to an embodiment of the present disclosure. The electronic device 1a includes a circuit structure 100a, an electronic unit 210, and an encapsulation layer 220a. The electronic unit 210 is disposed on the circuit structure 100a. The encapsulation layer 220a surrounds the electronic unit 210. The circuit structure 100a includes at least one first insulating layer I1 and at least one second insulating layer I2. The first insulating layer I1 is disposed between the electronic unit 210 and the second insulating layer I2, and a stiffness of the first insulating layer I1 is less than a stiffness of the second insulating layer I2. With the second insulating layer I2 having a greater stiffness being disposed at the side of the first insulating layer I1 away from the electronic unit 210, it is beneficial for supporting the first insulating layer I1. Moreover, with the first insulating layer I1 closer to the electronic unit 210 may having a smaller thickness, it is beneficial to arrange conductive elements (such as the first conductive layer C11) with smaller sizes in the first insulating layer I1. Therefore, it is beneficial to increase the I/O quantity of the electronic unit 210, so that the I/O density of the electronic device 1a can be enhanced. With the aforementioned design, it is beneficial to improve both the I/O density and the supportability of the electronic device 1a according to the present disclosure. The aforementioned “stiffness”, for example, may refer to the magnitude of Young's modulus. In general, when an object has a greater stiffness, the Young's modulus thereof is greater.

Specifically, in some embodiments, the electronic unit 210 is exemplarily a chip. For example, the chip may be a system on chip (SoC), a dynamic random-access memory (DRAM) chip, a high bandwidth memory (HBM) chip, a photonic integrated circuit (PIC), an application-specific integrated circuit (ASIC) chip, or other logic integrated circuit chips, but not limited thereto. The chip may include an active surface 211 having a pad PD and a back surface 212 opposite to the active surface 211. The pad PD, for example, may be an in-put/out-put pad (I/O pad). Herein, the chip faces the circuit structure 100a with the active surface 211, and the chip may be electrically connected to the circuit structure 100a via the pads PD of the active surface 211. According to an embodiment of the present disclosure, the electronic unit 210 may be an unpackaged chip, but not limited thereto. In the present disclosure, the active surface 211 may include active element layers, such as a transistor and related dielectric layers.

The circuit structure 100a is exemplarily a redistribution layer (RDL) structure. In the vertical direction D2, the circuit structure 100a includes a first insulating layer I11, a first insulating layer I12, a second insulating layer I21, and a second insulating layer I22 in sequence from the electronic unit 210 along a direction away from the electronic unit 210. The circuit structure 100a may further include a first conductive layer C11, a first conductive layer C12, a second conductive layer C21 and a second conductive layer C22 respectively disposed in the first insulating layer I11, the first insulating layer I12, the second insulating layer I21 and the second insulating layer I22. The vertical direction D2 may be, for example, parallel to a normal direction (not shown) of the surface 102 of the circuit structure 100a.

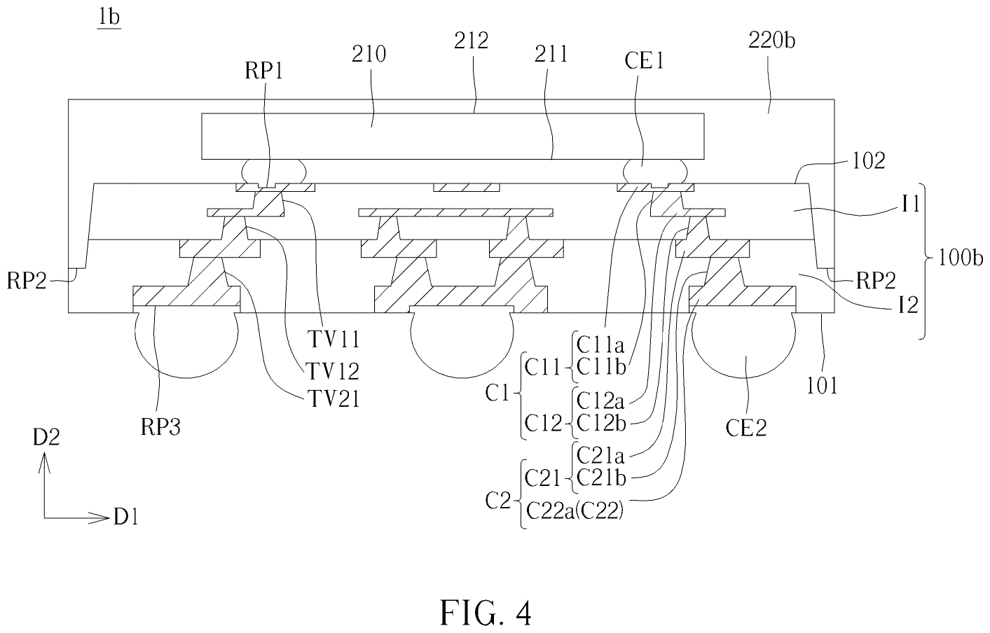

In FIG. 1, the number of the first insulating layers I1 is exemplarily two, and the two first insulating layers I1 are the first insulating layer I11 and the first insulating layer I12. The number of the second insulating layers I2 is exemplarily two, and the two second insulating layers I2 are the second insulating layer I21 and the second insulating layer I22. However, the present disclosure is not limited thereto. Hereinafter, when there are a plurality of first insulating layers I1, the first insulating layer 11 may represent one of the plurality of first insulating layers (such as the first insulating layers I11 and I12). Similarly, the second insulating layer I2 may represent one of the plurality of second insulating layers (such as the second insulating layers I21 and I22). In FIG. 1, the number of the first conductive layers C1 is exemplarily two, and the two first conductive layers C1 are the first conductive layer C11 and the first conductive layer C12. The number of the second conductive layers C2 is exemplarily two, and the two second conductive layers C2 are the second conductive layer C21 and the second conductive layer C22. However, the present disclosure is not limited thereto. Hereinafter, the first conductive layer C1 may represent one of the plurality of first conductive layers (such as the first conductive layers C11 and C12). Similarly, the second conductive layer C2 may represent one of the plurality of second conductive layers (such as the second conductive layers C21 and C22). For the sake of conciseness, the boundaries between the plurality of first insulating layers I1, the boundaries between the plurality of second insulating layers I2, the boundaries between the plurality of first conductive layers C1, and the boundaries between the plurality of second conductive layers C2 are not shown in FIG. 4 to FIG. 14.

In detail, the first conductive layer C11 may include a pad conductive layer C11a and a via conductive layer C11b, wherein the surface of the pad conductive layer C11a facing the electronic unit 210 may be formed with a concave portion RP1. Thereby, the bonding element CE1 may extend into the concave portion RP1, so that the bonding strength between the bonding element CE1 and the pad conductive layer C11a can be improved. The first conductive layer C12 may include a pad conductive layer C12a and a via conductive layer C12b. The second conductive layer C21 may include a pad conductive layer C21a and a via conductive layer C21b. The second conductive layer C22 may include pad conductive layers C22a and C22c. The via conductive layer may be filled into the hole of the insulating layer to electrically connect the conductive layers in different insulating layers. The pad conductive layer may serve as a connecting pad or a wire that extends laterally, but not limited thereto.

The pad conductive layer C11a has a thickness t11a, the pad conductive layer C12a has a thickness t12a, the pad conductive layer C21a has a thickness t21a, and the pad conductive layer C22a has a thickness t22a. The first insulating layer I11 has a thickness t11, the first insulating layer I12 has a thickness t12, the second insulating layer I21 has a thickness t21, and the second insulating layer I22 has a thickness t22. In the present disclosure, a thickness of an element may refer to the maximum length of the element in the vertical direction D2.

In some embodiments, the thickness of at least one first insulating layer I1 is less than the thickness of at least one second insulating layer I2. The aforementioned “the thickness of at least one first insulating layer I1 is less than the thickness of at least one second insulating layer I2” may refer that the thicknesses of corresponding portions of the first insulating layer I1 and the second insulating layer I2 are compared. For example, the thicknesses of the portions of the first insulating layer I1 and the second insulating layer I2 surrounding the pad conductive layer are compared, or the thicknesses of the portions of the first insulating layer I1 and the second insulating layer I2 surrounding both the pad conductive layer and the via conductive layer are compared. For example, the first insulating layer I11 is disposed with both the pad conductive layer C11a and the via conductive layer C11b, and the second insulating layer I21 is disposed with both the pad conductive layer C21a and the via conductive layer C21b. When comparing the thicknesses of the first insulating layer I11 and the second insulating layer I21, it may compare the total thickness of the first insulating layer I11 (i.e., the thickness t11) with the total thickness of the second insulating layer I21 (i.e., the thickness t21). When comparing the thicknesses of the first insulating layer I11 and the second insulating layer I22, since the second insulating layer I22 is only disposed with the pad conductive layers C22a and C22c but not disposed with a via conductive layer, it may compare the thickness of the portion of the first insulating layer I11 surrounding the pad conductive layer C11a (which equals to the thickness t11a of the pad conductive layer C11a) with the total thickness of the second insulating layer I22 (i.e., the thickness t22).

When there are a plurality of first insulating layers I1 and a plurality of second insulating layers I2, the aforementioned “the thickness of at least one first insulating layer I1 is less than the thickness of at least one second insulating layer I2” may refer that the thickness of at least one of the plurality of first insulating layers I1 is less than the thickness of at least one of the plurality of second insulating layers I2. In some embodiments, when there are the plurality of first insulating layers I1 and the plurality of second insulating layers I2, the aforementioned “the thickness of at least one first insulating layer I1 is less than the thickness of at least one second insulating layer I2” may refer that the thickness of any one of the plurality of first insulating layers I1 is less than the thickness of any one of the plurality of second insulating layers I2. In this embodiment, the thickness t11 of the first insulating layer I11 is less than the thickness t21 of the second insulating layer I21, and the thickness t12 of the first insulating layer I12 is less than the thickness t21 of the second insulating layer I21.

In some embodiments, the thickness of at least one first conductive layer C1 is less than the thickness of at least one second conductive layer C2. The thickness in the aforementioned “the thickness of at least one first conductive layer C1 is less than the thickness of at least one second conductive layer C2” may refer to the thicknesses of the pad conductive layer in the first conductive layer C1 and the thickness of the pad conductive layer in the second conductive layer C2. For example, when comparing the thicknesses of the first conductive layer C11 and the second conductive layer C21, it may compare the thickness t11a of the pad conductive layer C11a with the thickness t21a of the pad conductive layer C21a.

In addition, when there are a plurality of first conductive layers C1 and a plurality of second conductive layers C2, the aforementioned “the thickness of at least one first conductive layer C1 is less than the thickness of at least one second conductive layer C2” may refer that the thickness of at least one of the plurality of first conductive layers C1 is less than the thickness of at least one of the plurality of second conductive layers C2. In some embodiments, when there are the plurality of first conductive layers C1 and the plurality of second conductive layers C2, the aforementioned “the thickness of at least one first conductive layer C1 is less than the thickness of at least one second conductive layer C2” may refer that the thickness of any one of the plurality of first conductive layers C1 is less than the thickness of any one of the plurality of second conductive layers C2. In this embodiment, the thickness t11a is less than the thickness t21a and less than the thickness t22a, and the thickness t12a is less than the thickness t21a and less than the thickness t22a. Therefore, it may be regarded that the thickness of the first conductive layer C11 is less than the thickness of the second conductive layer C21 and less than the thickness of the second conductive layer C22, and the thickness of the first conductive layer C12 is less than the thickness of the second conductive layer C21 and less than the thickness of the second conductive layer C22. In addition, the thicknesses t11a, t12a, t21a, and t22a in FIG. 1 may satisfy the following condition: t11a<t12a<t21a<t22a. That is, the pad conductive layer farther away from the electronic unit 210 may be arranged with a greater thickness.

The electronic device 1a may further include a plurality of bonding elements CE1 and a plurality of bonding elements CE2. The plurality of bonding elements CEL are disposed between the electronic unit 210 and the circuit structure 100a. The electronic unit 210 and the circuit structure 100a may be electrically connected via the plurality of bonding elements CE1. The plurality of bonding elements CE2 are disposed on a surface 101 of the circuit structure 100a away from the electronic unit 210. The circuit structure 100a may be electrically connected to other external elements (not shown) via the bonding elements CE2. In addition, the bonding elements CE1 and CE2 may be electrically connected via the first conductive layers C1 and the second conductive layers C2.

The bonding elements CE1 and CE2 may be made of a conductive material to provide a conductive function. The conductive material may include a metal, such as tin, tin-silver, tin-silver-bismuth, tin-gold, tin-nickel-gold, nickel-gold, copper, other suitable materials or a combination thereof, but not limited thereto. The conductive materials of the plurality of bonding elements CE1 and CE2 may be independently the same or different. The plurality of bonding elements CE1 and CE2 may independently be, for example, bumps, solder balls or pads, but not limited thereto. Herein, the plurality of bonding elements CE1 and CE2 are exemplarily metal bumps. In this embodiment, a size of at least one of the plurality of bonding elements CE1 is less than a size of at least one of the plurality of bonding elements CE2. In addition, the sizes of the plurality of bonding elements CE1 may be the same, and the sizes of the plurality of bonding elements CE2 may be the same. The aforementioned “size” may refer to the maximum length of each of the bonding elements CE1 and CE2 in one direction. For example, when the bonding element CE1 is a sphere, the size of the bonding element CE1 is the diameter of the sphere. According to an embodiment of the present disclosure, the size of the bonding element CE1 is greater than or equal to 1 micrometer (μm) and less than or equal to 50 μm, and the size of the bonding element CE2 is greater than or equal to 50 μm and less than or equal to 250 μm, but not limited thereto.

The circuit structure 100a may further include a heat dissipation layer to provide a heat dissipation function. For example, in this embodiment, the pad conductive layer C22a of the second conductive layer C22 is configured to be electrically connected to the bonding elements CE1 and CE2, and may have a partial heat dissipation capability. The circuit structure 100a may further include a pad conductive layer C22c in the second conductive layer C22. The pad conductive layer C22c is not configured to be electrically connected to the bonding elements CE1 and CE2, but can serve as a heat dissipation layer to further improve the heat dissipation capability. In this embodiment, the pad conductive layer C22c serve as the heat dissipation layers. The number of the pad conductive layers C22c is two and the pad conductive layers C22c are disposed in the second insulating layer I22, but not limited thereto. In other embodiments, the material, the number and the disposed position of the heat dissipation layer can be adjusted according to actual needs. For example, the heat dissipation layer may not be a part of the first conductive layer C1 and the second conductive layer C2 but a layer additionally formed. In some embodiments, the thermal conductivity of the heat dissipation layer may be greater than or equal to 50 W/mk and less than or equal to 505 W/mk. The material of the heat dissipation layer may include, for example, a metal, graphene, a thermal conductive paste, other suitable materials or a combination thereof, but not limited thereto. The heat dissipation layer may be disposed in at least one first insulating layer I1 and/or at least one second insulating layer I2, but not limited thereto. Furthermore, the temperature of the conductive layer closer to the electronic unit 210 is usually higher than the temperature of the conductive layer farther from the electronic unit 210, with the conductive layers being arranged with different thicknesses, the temperature difference between the conductive layers may be increased. Since heat diffuses from high temperature to low temperature to achieve thermal equilibrium, through the above design, an active heat dissipation path can be formed to enhance the heat dissipation effect of the electronic device 1a, but not limited thereto.

The stiffness of at least one first insulating layer I1 may be less than the stiffness of the encapsulation layer 220a. Thereby, the encapsulation layer 220a with the greater stiffness can support the first insulating layer I1. The coefficient of thermal expansion of the encapsulation layer 220a may be less than the coefficient of thermal expansion of the at least one first insulating layer 11, and the coefficient of thermal expansion of the encapsulation layer 220a may be less than the coefficient of thermal expansion of the at least one second insulating layer I2. Thereby, it is beneficial to dispose the electronic unit 210 with high power or high heat generation properties in the encapsulation layer 220a, but not limited thereto.

The materials of the first insulating layers I11 and I12 may independently include an organic material or an inorganic material, such as a photosensitive polyimide (PSPI) resin, a polyimide (PI) resin, poly (p-phenylene benzobisoxazole) (PBO), other suitable materials or a combination thereof, but not limited thereto. The coefficients of thermal expansion (CTE) of the first insulating layers I11 and I12 may independently be 25 ppm/C to 50 ppm/° C. The Young's moduli of the first insulating layers I11 and I12 may independently be 0.5 GPa to 5 GPa.

The materials of the second insulating layers I21 and I22 may independently include organic materials or inorganic materials, such as an epoxy, a polymer, other suitable materials or a combination thereof, but not limited thereto. In addition, the second insulating layers I21 and I22 may be added with fillers to adjust the coefficients of thermal expansion and/or stiffness of the second insulating layers I21 and I22. The particle sizes of the fillers may be, for example, 0.05 μm to 10 μm. The coefficients of thermal expansion of the second insulating layers I21 and I22 may independently be 10 ppm/° C. to 25 ppm/C. The Young's moduli of the second insulating layers I21 and I22 may independently be 10 GPa to 25 GPa, and the tensile strengths of the second insulating layers I21 and I22 may independently be 50 MPa to 110 MPa.

The material of the encapsulation layer 220a may include organic materials or inorganic materials, such as an epoxy, a polymer, silicon oxide, silicon nitride, other suitable materials or a combination thereof, but not limited thereto. In addition, the encapsulation layer 220a may be added with fillers to adjust the coefficient of thermal expansion and/or stiffness of the encapsulation layer 220a. The particle sizes of the fillers may be, for example, 0.05 μm to 25 μm. The coefficient of thermal expansion of the encapsulation layer 220a may be 3 ppm/C to 12 ppm/C. The Young's modulus of the encapsulation layer 220a may be 5 GPa to 20 GPa.

The first conductive layers C11 and C12 and the second conductive layers C21 and C22 are exemplarily single-layer structures. The materials of the first conductive layers C11 and C12 and the second conductive layers C21 and C22 may independently include iron, aluminum, copper, nickel, tungsten, gold, platinum, other suitable materials or a combination thereof, but not limited thereto. According to an embodiment of the present disclosure, the materials of the first conductive layers C11 and C12 and the second conductive layers C21 and C22 may include copper. In other embodiments, the first conductive layers C11 and C12 and the second conductive layers C21 and C22 may be multi-layer structures. For example, each of the first conductive layers C11 and C12 and the second conductive layers C21 and C22 may further include a barrier layer (not shown). A material of the barrier layer, for example, may include titanium tantalum (Ta), copper, other suitable materials or a combination thereof, but not limited thereto.

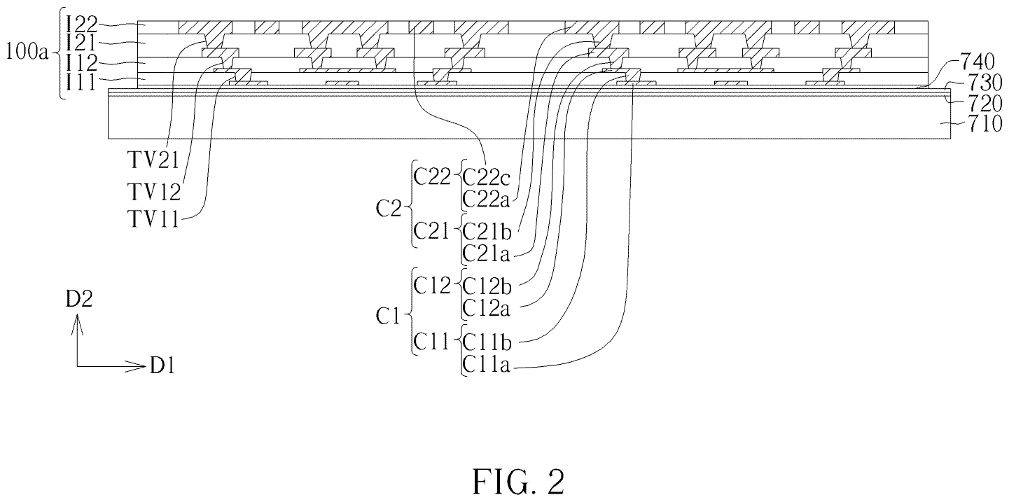

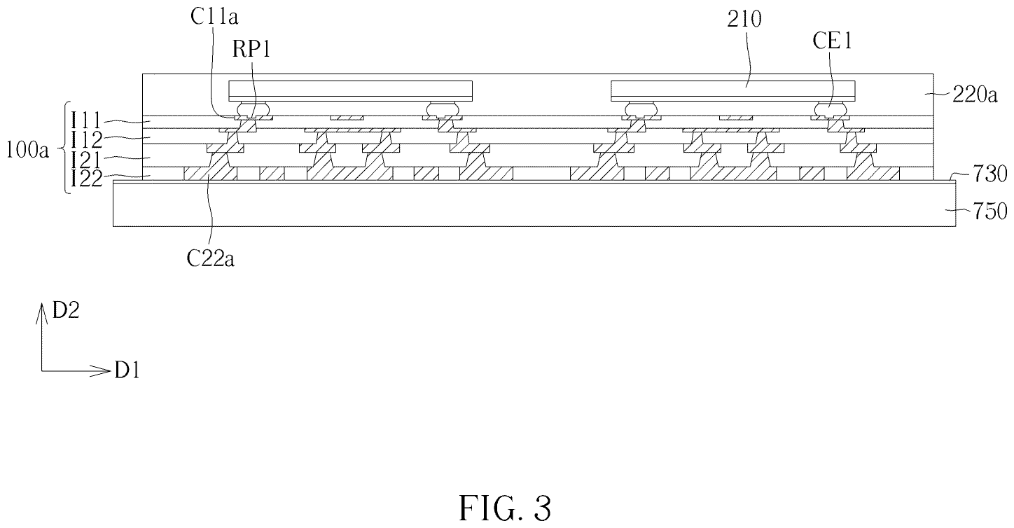

Please refer to FIG. 2 to FIG. 3, which are schematic cross-sectional views showing a method for manufacturing the electronic device 1a shown in FIG. 1. First, as shown in FIG. 2, the circuit structure 100a is provided on a carrier 710. The carrier 710 is configured to carry and support the circuit structure 100a subsequently formed. The carrier 710 may include, for example, a glass, a wafer, a steel plate or other substrates suitable for carrying and supporting the circuit structure 100a, but not limited thereto. In some embodiments, the carrier 710 may also include a flexible substrate disposed on a hard substrate. The flexible substrate may include, for example, polyimide (PI) or polyethylene terephthalate (PET), but not limited thereto. The carrier 710 is formed with an adjustment layer 720, a debonding layer 730 and a seed layer 740, wherein the adjustment layer 720 is disposed between the carrier 710 and the debonding layer 730, and the debonding layer 730 is disposed between the adjustment layer 720 and the seed layer 740. The adjustment layer 720 and the debonding layer 730 may blanketly cover the carrier 710, and the seed layer 740 may partially cover the carrier 710. The coverage ratio of the seed layer 740 to the carrier 710 is about 75% to 95%. Thereby, the warpage degree of the circuit structure 100a subsequently formed may be reduced. The adjustment layer 720 is configured to reduce the warpage degree of the circuit structure 100a subsequently formed. The adjustment layer 720 is configured to have a warpage direction opposite to that of the circuit structure 100a. For example, according to the materials of the first insulating layers I11 and I12 and the second insulating layers I21 and I22 of the circuit structure 100a, it is known that the circuit structure 100a will warpage upwardly, so that the adjustment layer 720 may be selected from a material that will warpage downwardly. That is, the adjustment layer 720 may be made of a material having a warpage tendency opposite to that of the circuit structure 100a. The adjustment layer 720 may be a single-layer structure or a multi-layer structure (not shown), and the material of the adjustment layer 720 may include an inorganic material, such as silicon oxide, silicon nitride, silicon oxynitride, other suitable materials or a combination thereof. According to some embodiments, the adjustment layers 720 may be formed on two opposite surfaces of the carrier 710. The debonding layer 730 is configured to separate the carrier 710 from the element formed later after the subsequent steps are completed. The debonding layer 730 may include, for example, a polyethylene (PE) release film, a PET release film, an oriented polypropylene (OPP) release film and a composite release film (i.e., the substrate is composed of two or more materials), but not limited thereto. The seed layer 740 may include, for example, titanium, tungsten, nickel, other suitable materials or a combination thereof. According to an embodiment, the seed layer 740 may include titanium copper.

Forming the circuit structure 100a may include steps as follows. First, a patterned photoresist (not shown) is formed on the seed layer 740 to define the position of the pad conductive layer C11a. The patterned photoresist has at least one opening to expose a portion of the seed layer 740. Next, a conductive film layer is formed on the exposed portion of the seed layer 740. Next, the patterned photoresist is removed to complete the manufacture of the pad conductive layer C11a. The conductive film layer may be formed on the exposed portion of the seed layer 740 by an electroplating process, a chemical electroplating process, a physical vapor deposition process or other suitable processes. In some embodiments, after the patterned photoresist is removed, the seed layer 740 located below the patterned photoresist may also be removed, but not limited thereto. The seed layer 740 located below the patterned photoresist may also be reserved, as shown in FIG. 2. Next, the first insulating layer I11 is formed on the carrier 710, wherein the first insulating layer I11 covers the pad conductive layer C11a. The first insulating layer I11 may be formed by a coating process, but not limited thereto. Next, at least one hole TV11 is formed in the first insulating layer I11 to expose the pad conductive layer C11a below. The hole TV11 may be, for example, formed by an exposure and photolithography process, but not limited thereto. Next, another seed layer (not shown) may be optionally formed to blanketly cover the first insulating layer I11 and to fill into the hole TV11. Next, a patterned photoresist (not shown) may be formed on the another seed layer to define the position of the pad conductive layer C12a, and the patterned photoresist has at least one opening to expose a portion of the another seed layer. Next, a conductive film layer is formed on the exposed portion of the another seed layer, and then the patterned photoresist and the another seed layer located thereunder are removed to complete the manufacture of the via conductive layer C11b and the pad conductive layer C12a. Since the via conductive layer C11b and the pad conductive layer C12a may be formed in the same step, the via conductive layer C11b and the pad conductive layer C12a may also be regarded as the same conductive layer. Next, the above steps may be repeated to sequentially form the first insulating layer I12, the hole TV12, the via conductive layer C12b, the pad conductive layer C21a, the second insulating layer I12, the hole TV21, the via conductive layer C21b and the pad conductive layers C22a and C22c. As last, the second insulating layer I22 is formed to cover the pad conductive layers C22a and C22c and fill into the gaps between the pad conductive layers C22a and C22c, and then a planarization process, such as a chemical mechanical polishing process or a sandblasting process, may be performed to expose the pad conductive layers C22a and C22c form the second insulating layer I22, so as to complete the manufacture of the circuit structure 100a. Next, a carrier 750 may be provided on the second insulating layer I22, and the carrier 750 may be disposed with a debonding layer 730. Next, the circuit structure 100a in FIG. 2 is turned over, and the carrier 710 and the adjustment layer 720 and the debonding layer 730 disposed on the carrier 710 are removed. For details about the carrier 750, references may be made to the related description of the carrier 710.

Next, please refer to FIG. 3, the pad conductive layer C11a may be subjected to an etching process or a surface treatment process to roughen the surface thereof and to form concave portions RP1, and the seed layer 740 disposed on the pad conductive layer C1a and the first insulating layer I11 may be removed at the same time. In some embodiments, the etching process may include a dry etching process, a wet etching process or other suitable etching processes. Next, the electronic unit 210 is connected and fixed to the circuit structure 100a via the bonding elements CE1, wherein each of the bonding elements CE1 may be disposed corresponding to one pad conductive layer C1a. In some embodiments, the bonding elements CE1 may be firstly formed on the pad conductive layer C11a, and then the electronic unit 210 is disposed thereon. In some other embodiments, the bonding elements CE1 may be firstly formed at one side (such as the side of active surface) of the electronic unit 210, and then the electronic unit 210 may be fixed and bonded to the circuit structure 100a. Afterwards, the encapsulation layer 220a surrounding the electronic unit 210 may be formed. The encapsulation layer 220a may be, for example, formed by a molding process, but not limited thereto. Next, the carrier 750 and the debonding layer 730 thereon may be removed to expose the pad conductive layer C22a, and then the bonding elements CE2 may be formed on the pad conductive layer C22a. As last, a cutting process may be performed to cut the electronic device in FIG. 3 into at least two parts, so as to obtain two electronic devices 1a shown in FIG. 1. In this embodiment, the carrier 750 and the debonding layer 730 disposed thereon are firstly removed, the bonding elements CE2 are formed, and then the cutting process is performed, but not limited thereto. The carrier 750 and the debonding layer 730 disposed thereon may be removed before or after the cutting process, and the bonding elements CE2 may be formed before or after the cutting process. In the present disclosure, the term “surrounding” refers that an element A contacts at least a portion of a side surface of an element B in a cross-sectional view.

Please refer to FIG. 4, which is a schematic cross-sectional view showing an electronic device 1b according to another embodiment of the present disclosure. The electronic device 1b includes a circuit structure 100b, an electronic unit 210, and an encapsulation layer 220b. The electronic unit 210 is disposed on the circuit structure 100b. The encapsulation layer 220b surrounds the electronic unit 210. The circuit structure 100b includes at least one first insulating layer I1 and at least one second insulating layer I2. The first insulating layer I1 is disposed between the electronic unit 210 and the second insulating layer I2, and the stiffness of the first insulating layer I1 is less than the stiffness of the second insulating layer I2.

Compared with the electronic device 1a in FIG. 1, in the electronic device 1b, concave portions RP2 are formed on the surface of the second insulating layer I2 facing the first insulating layer I1. The concave portions RP2 are located at the periphery of the second insulating layer I2. The encapsulation layer 220b extends into the concave portions RP2 along the side surfaces of the first insulating layer I1. In other words, the encapsulation layer 220b surrounds both the electronic unit 210 and the first insulating layer I1, and the encapsulation layer 220b extends into the second insulating layer I2. Thereby, the encapsulation layer 220b can protect the side surface of the first insulating layer I1, and can strengthen the support for the first insulating layer I1 or can block moisture. The encapsulation layer 220b extending into the second insulating layer I2 can provide an anchoring and engaging effect, so that the bonding strength between the encapsulation layer 220b and the second insulating layer I2 can be enhanced. Furthermore, the second conductive layer C22 of the circuit structure 100b includes the pad conductive layer C22a but does not include the pad conductive layer C22c shown in FIG. 1. In addition, the pad conductive layer C22a may be formed with a concave portion RP3, and the bonding element CE2 may be formed on the concave portion RP3 of the pad conductive layer C22a to improve the bonding force.

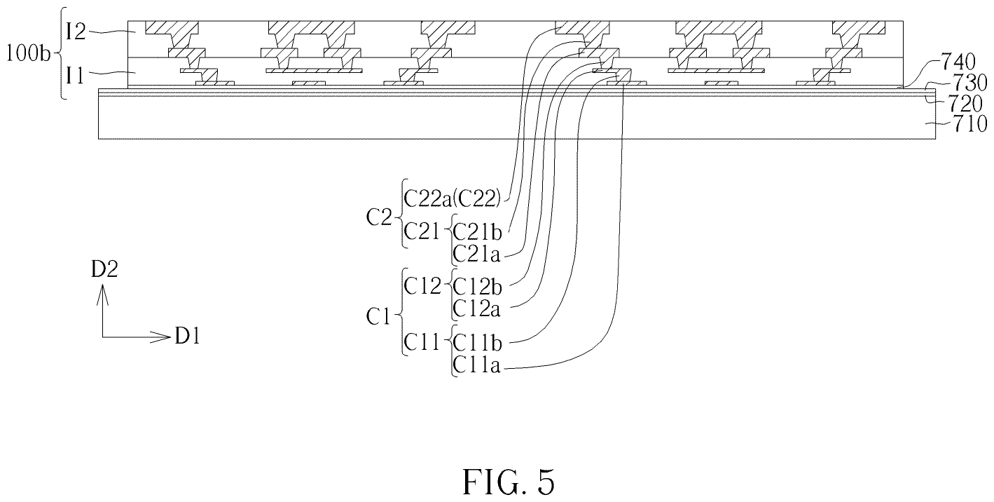

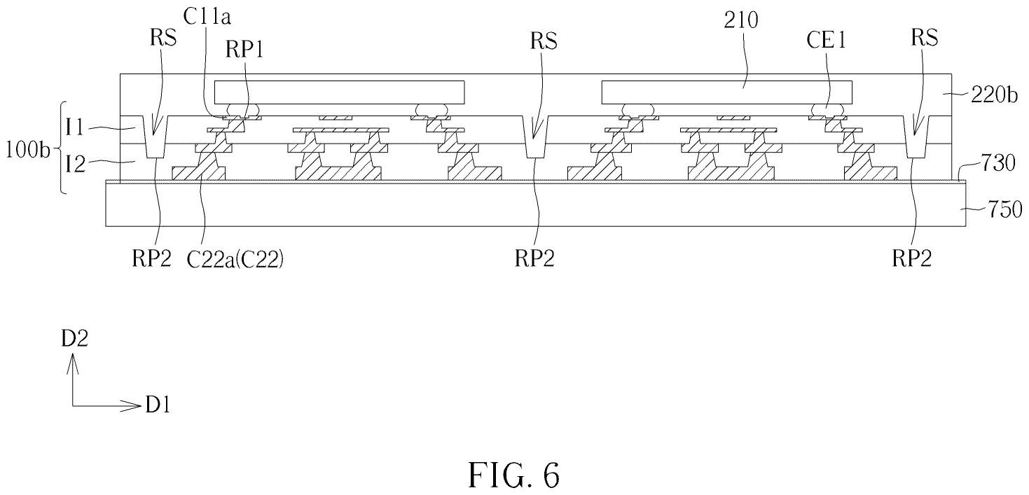

Please refer to FIG. 5 and FIG. 6, which are schematic cross-sectional views showing a method for manufacturing the electronic device 1b shown in FIG. 4. First, as shown in FIG. 5, the circuit structure 100b is provided on a carrier 710. The main difference between the circuit structure 100b and the circuit structure 100a is that the second conductive layer C22 of the circuit structure 100b does not include the pad conductive layer C22c serving as the heat dissipation layer. When forming the second conductive layer C22, only the pad conductive layer C22a may be formed by changing the arrangement of the patterned photoresist. Next, a carrier 750 may be provided on the second insulating layer I2. Afterwards, the electronic device in FIG. 5 is turned over, and then the carrier 710 and the adjustment layer 720 and the debonding layer 730 disposed on the carrier 710 are removed.

Next, please refer to FIG. 6. The pad conductive layer C11a may be subjected to an etching process or a surface treatment process to roughen the surface thereof, and even to form a concave portion RP1. Next, the electronic unit 210 is fixed and bonded to the pad conductive layer C11a of the circuit structure 100b via the bonding elements CE1. Next, portions of the first insulating layer I1 are removed to form recesses RS, and concave portions RP2 may be formed on the second insulating layer I2 corresponding to the recesses RS at the same time. Next, an encapsulation layer 220b surrounding the electronic unit 210 is formed, wherein the encapsulation layer 220b is filled into the recesses RS. Thereby, the encapsulation layer 220b surrounds the first insulating layer I1 and extends into the concave portions RP2 of the second insulating layer I2. Afterwards, the carrier 750 and the debonding layer 730 disposed thereon may be removed to expose the pad conductive layer C22a, and the pad conductive layer C22a may be subjected to an etching process or a surface treatment process to roughen the surface thereof and form concave portions RP3. Next, bonding elements CE2 are formed on the pad conductive layer C22a. As last, a cutting process may be performed to cut the electronic device in FIG. 6 into a plurality of parts. For example, the electronic device in FIG. 6 may be cut along the center line of the recess RS at the left side and the center line of the recess RS at the right side to remove the portions outside the recess RS at the left side and recess RS at the right side, and may be cut along the center line of the recess RS in the middle, so that two electronic devices 1b shown in FIG. 4 are obtained. For other details of the method for manufacturing the electronic device 1b, references may be made to the relevant description of the method for manufacturing the electronic device 1a and are omitted herein.

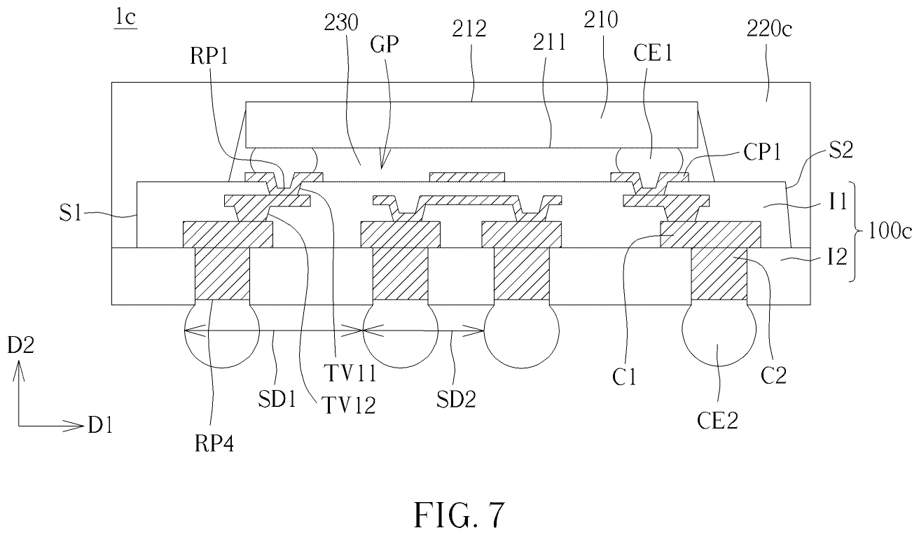

Please refer to FIG. 7, which is a schematic cross-sectional view showing an electronic device 1c according to yet another embodiment of the present disclosure. The electronic device 1c includes a circuit structure 100c, an electronic unit 210, an encapsulation layer 220c, a plurality of bonding elements CE1, a plurality of bonding elements CE2, and a filler 230. The main difference between the electronic device 1c and the electronic device 1b is that the electronic device 1c further includes the filler 230, the surface of the second insulating layer I2 facing the first insulating layer I1 is not formed with concave portions RP2, and the encapsulation layer 220c extends to the surface of the second insulating layer I2 facing the first insulating layer I1 along the side surfaces of the first insulating layer I1. The encapsulation layer 220c surrounds the electronic unit 210, the filler 230 and the first insulating layer I1. Thereby, the encapsulation layer 220c can simultaneously protect the electronic unit 210, the filler 230 and the first insulating layer I1, and the support for the first insulating layer I1 can be strengthened, so as to improve the supportability of the electronic device 1c. The filler 230 is disposed in the gap GP between the plurality of bonding elements CE1. The filler 230 may include acrylic, epoxy, resin, photoresist, other suitable materials or a combination thereof, but not limited thereto. The filler 230 can protect and fix the bonding elements CE1, so that the probability of peeling off or poor electrical connection of the bonding elements CE1 caused by external forces can be reduced. Furthermore, the first insulating layer I1 has a vertical side surface S1 and an inclined side surface S2. Therefore, the first insulating layer I1 has an asymmetric cross section. In addition, the spaced distances (such as the spaced distances SD1 and SD2) between every two adjacent bonding elements CE2 may be different. It should be noted that the spaced distance SD2 between two adjacent bonding elements CE2 closer to the middle of the electronic device 1c is smaller than the spaced distance SD1 between two adjacent bonding elements CE2 closer to the outer side of the electronic device 1c. Therefore, the possibility that the bonding elements CE2 being broken due to the bonding stress generated by the electronic device 1c being bonded to an external element (such as a printed circuit board) can be reduced, but not limited thereto.

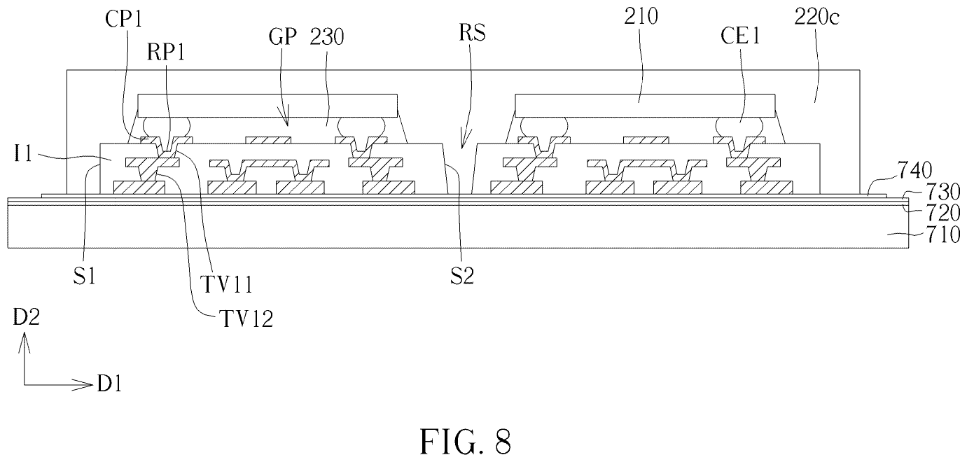

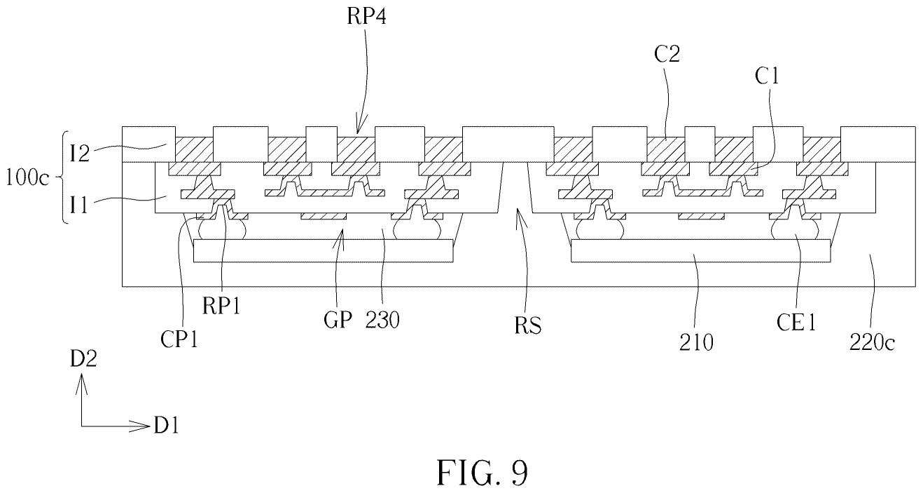

Please refer to FIG. 8 and FIG. 9, which are schematic cross-sectional views showing a method for manufacturing the electronic device 1c shown in FIG. 7. First, as shown in FIG. 8, the first insulating layer I1 is provided on a carrier 710. The carrier 710 is formed with an adjustment layer 720, a debonding layer 730 and a seed layer 740. The first insulating layer I1 may be a single-layer structure or a multi-layer structure. That is, the first insulating layer I1 may include at least one first insulating layer (which may refer to the first insulating layers I11 and I12 in FIG. 1). For the sake of conciseness, the boundaries between the multiple first insulating layers are not shown herein. At least one first conductive layer (which may refer to the first conductive layers C11 and C12 in FIG. 1) is disposed in at least one first insulating layer (which may refer to the first insulating layers I11 and I12 in FIG. 1), and at least one pad conductive layer CP1 is disposed on the first insulating layer I1 and is electrically connected to the first conductive layer C1. For details about how to form the first insulating layer I1, the first conductive layer C1 and the pad conductive layer CP1, references may be made to the above related description and are omitted herein.

Afterwards, the electronic unit 210 is connected to the pad conductive layer CP1 via the bonding elements CE1, and a filler 230 is provided in the gaps GP between the plurality of bonding elements CE1. Next, a portion of the first insulating layer I1 is removed to form a recess RS. The first insulating layer I1 has inclined side surfaces S2 corresponding to the recess RS, and the left and right sides of the first insulating layer I1 are not removed and remain to be vertical side surfaces S1. Next, an encapsulation layer 220c is formed to surround the first insulating layer I1, the filler 230, and the electronic unit 210, wherein the encapsulation layer 220c is filled into the recess RS. Next, the electronic device in FIG. 8 is turned over, and the carrier 710 and the adjustment layer 720 and the debonding layer 730 disposed on the carrier 710 are removed. At this time, the seed layer 740 still covers a side of the first insulating layer I1 away from the electronic unit 210.

Next, please refer to FIG. 9. A patterned photoresist (not shown) is formed on the seed layer 740 to define the position of the second conductive layer C2. The patterned photoresist has at least one opening exposing a portion of the seed layer 740. Next, a conductive film layer is formed on the portion of the seed layer 740 exposed from the opening, and then the patterned photoresist and the seed layer 740 thereunder are removed to complete the manufacture of the second conductive layer C2. In FIG. 9, the seed layer 740 is disposed between the second conductive layer C2 and the first conductive layer C1 under the second conductive layer C2. For the sake of conciseness, the seed layer 740 is not shown herein.

Afterwards, a second insulating layer I2 is formed to cover the second conductive layer C2 and fill into the gaps between the second conductive layers C2. Next, a planarization process, such as a chemical mechanical polishing process or a sandblasting process, is performed to expose the second conductive layer C2 from the second insulating layer I2, but not limited thereto. The second conductive layer C2 may be subjected to an etching process or a surface treatment process to roughen the surface thereof and form concave portions RP4 to enhance the bonding force between the second conductive layer C2 and the bonding elements CE2. Next, the bonding elements CE2 are formed on the second conductive layer C2. At last, a cutting process may be performed to cut the electronic device in FIG. 9 into at least two parts. For example, the electronic device in FIG. 9 may be cut along the center line of the recess RS to obtain two electronic devices 1c in FIG. 7. For other details of the method for manufacturing the electronic device 1c, references may be made to the relevant description of the methods for manufacturing the electronic devices 1a and 1b, and are omitted herein.

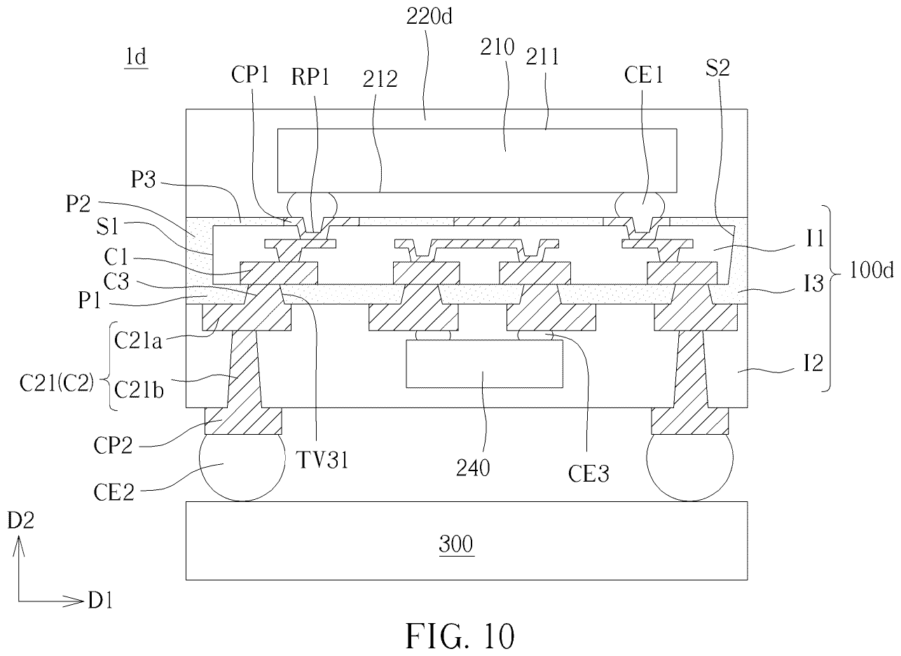

Please refer to FIG. 10, which is a schematic cross-sectional view showing an electronic device 1d according to yet another embodiment of the present disclosure. The electronic device 1d includes a circuit structure 100d, electronic units 210 and 240, an encapsulation layer 220d, a plurality of bonding elements CE1, a plurality of bonding elements CE2, a plurality of bonding elements CE3, and an external element 300, wherein the external element 300 may include a circuit board. According to some embodiments, the external element 300 may include another package device bonded via the bonding elements CE2 and may be similar to a 2.5D or 3D package structure, but not limited thereto. The electronic device 1d may be an integrated fan-out package unit. The electronic unit 210 is disposed on the circuit structure 100d, and the electronic unit 240 is disposed in the circuit structure 100d. The encapsulation layer 200d surrounds the electronic unit 210. The external element 300 is electrically connected to the circuit structure 100d. The plurality of bonding elements CE1 are disposed between the electronic unit 210 and the circuit structure 100d to electrically connect the electronic unit 210 and the circuit structure 100d. The plurality of bonding elements CE2 are disposed between the circuit structure 100d and the external element 300 to electrically connect the circuit structure 100d and the external element 300. The plurality of bonding elements CE3 are disposed on a surface of the electronic unit 240 closer to the inside of the circuit structure 100d to electrically connect the electronic unit 240 and a conductive layer inside the circuit structure 100d (herein, directly contacting the second conductive layer C2), so that the electronic unit 240 is electrically connected to the electronic unit 210 (not shown). The electronic device 1d may optionally further include a filler (not shown) filled into the gap between two of the plurality of bonding elements CE1 and/or the gap between two of the plurality of bonding elements CE2 and/or the gap between two of the plurality of bonding elements CE3. For details of the filler, reference may be made to the description of the filler 230 in FIG. 7.

The circuit structure 100d includes at least one first insulating layer I1, at least one second insulating layer I2, and at least one third insulating layer 13. The first insulating layer I1 is disposed between the electronic unit 210 and the second insulating layer I2, and the stiffness of the first insulating layer I1 is less than the stiffness of the second insulating layer I2. The third insulating layer 13 surrounds the first insulating layer I1, and the stiffness of the first insulating layer I1 is less than the stiffness of the third insulating layer 13. With the third insulating layer 13 surrounding the first insulating layer I1, the supporting force can be provided through the side surfaces (such as the vertical side surface S1 and the inclined side surface S2) of the first insulating layer I1. In this embodiment, the third insulating layer 13 may include a first portion P1, a second portion P2 and a third portion P3. The first portion P1 is disposed at a side of the first insulating layer I1 away from the electronic unit 210, the second portion P2 surrounds the first insulating layer I1, and the third portion P3 is disposed between the first insulating layer I1 and the electronic unit 210. Thereby, the third insulating layer 13 may completely cover the first insulating layer I1, which is beneficial to provide more complete protection and support for the first insulating layer I1.

The circuit structure 100d may further include at least one first conductive layer C1 disposed in the first insulating layer I1, at least one second conductive layer C2 disposed in the second insulating layer I2, and at least one third conductive layer C3 disposed in the third insulating layer 13. The first conductive layer C1, the second conductive layer C2 and the third conductive layer C3 may be electrically connected to form wires in the vertical direction D2 and/or the horizontal direction D1, so as to transmit signals in the vertical direction D2 and/or the horizontal direction D1. The horizontal direction D1 and the vertical direction D2 are perpendicular to each other.

In this embodiment, the electronic unit 240 is disposed in the second insulating layer I2. The second insulating layer I2 surrounds the electronic unit 240. The electronic unit 240 and the electronic unit 210 are located at different side of the first insulating layer I1 in the vertical direction D2. In addition, the electronic unit 240 may completely or partially overlap the electronic unit 210 in the vertical direction D2, which is beneficial to increase the maximum applied rate of planar space, so that the arrangement of the electronic elements in the electronic device 1d can be denser, and the current trend of miniaturization of electronic products can be satisfied. In addition, the electronic unit 240 and the electronic unit 210 may be connected via a wire in the vertical direction D2, which is less likely to cause signal loss and can provide a better signal transmission effect compared to be connected with a wire in the horizontal direction D1.

In some embodiments, the electronic unit 240 may be a passive element, such as a resistor, a capacitor, or an inductor, but not limited thereto. In some embodiments, the electronic unit 240 may also be an active element, such as a chip of a different type from the electronic unit 210, but not limited thereto.

The external element 300 may be, for example, a printed circuit board (PCB), a package substrate, or a substrate like PCB (SLP), but not limited thereto. Any carrier capable of providing an electrical connection function can serve as the external element 300 of the present disclosure, such as a carrier including an insulating layer and a wire disposed therein and thus capable of providing an electrical connection function. According to an embodiment of the present disclosure, the external element 300 may include a substrate, redistribution layer structures formed on the upper surface and the lower surface of the substrate, and through holes penetrating the substrate, and the substrate may include glass or silicon.

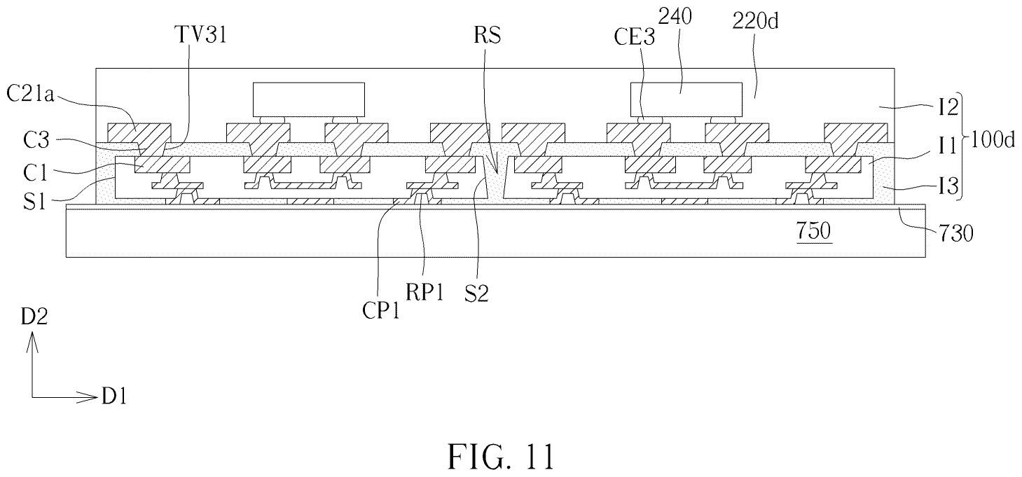

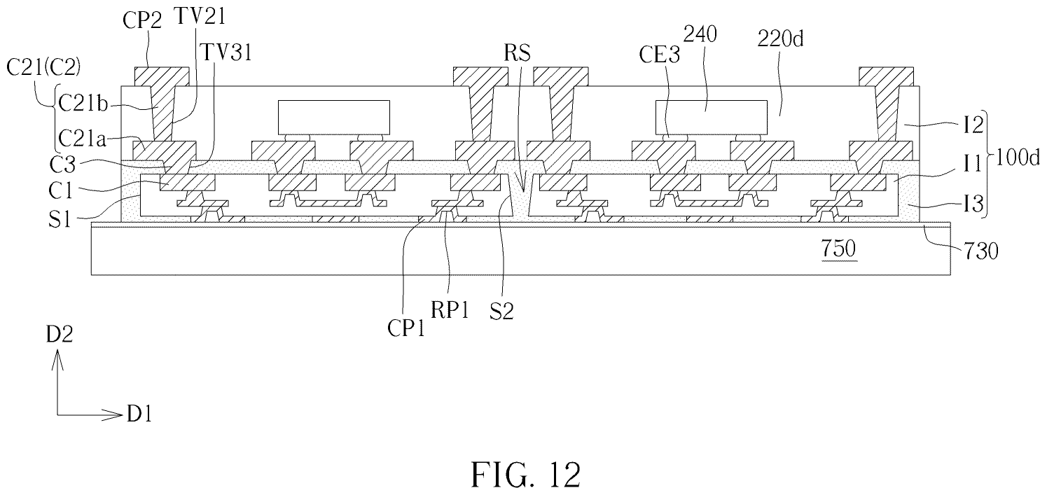

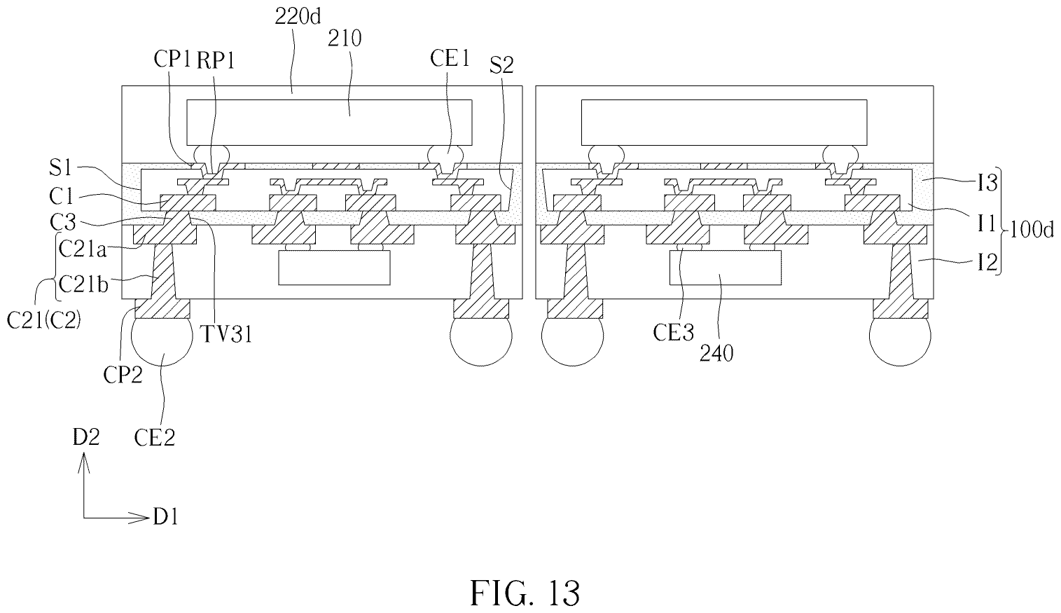

Please refer to FIG. 11 to FIG. 13, which are schematic cross-sectional views showing a method for manufacturing the electronic device 1d shown in FIG. 10. First, the first insulating layer I1 is provided on a carrier 710 (which may refer to FIG. 8). The carrier 710 is formed with an adjustment layer 720, a debonding layer 730 and a seed layer 740. For this part, references may be made to the description of FIG. 8, and are omitted herein. At this stage, the carrier 710 is located below the first insulating layer I1. Next, a carrier 750 may be provided above the first insulating layer I1, and the carrier 750 is disposed with a debonding layer 730 thereon. Next, the carrier 710, the first insulating layer I1 and the carrier 750 are turned over together, and the carrier 710 and the adjustment layer 720 and the debonding layer 730 disposed on the carrier 710 are removed. As shown in FIG. 11, at this stage, the carrier 750 is located below the first insulating layer I1, and then the seed layer 740 is removed. Next, a portion of the first insulating layer I1 is removed to form a recess RS. The first insulating layer I1 has inclined side surfaces S2 corresponding to the recess RS, and the left and right sides of the first insulating layer I1 are not removed and remain to be vertical side surfaces S1. Next, a third insulating layer 13 surrounding and covering the first insulating layer I1 is formed, wherein the third insulating layer 13 is filled into the recess RS and filled into the gap between the debonding layer 730 and the first insulating layer I1. The third insulating layer 13 may be, for example, formed by a molding process.

Next, at least one hole TV31 is formed in the third insulating layer 13 to expose the first conductive layer C1 below, and then another seed layer (not shown) is optionally formed to blanketly cover the third insulating layer 13 and filled into the hole TV31. Next, a patterned photoresist (not shown) is formed on the another seed layer to define the position of the pad conductive layer C21a. The patterned photoresist has at least one opening to expose a portion of the another seed layer. Next, a conductive film layer is formed on the exposed portion of the another seed layer, and then the patterned photoresist and the another seed layer thereunder are removed to complete the manufacture of the third conductive layer C3 (herein, the via conductive layer) and the pad conductive layer C21a. Since the third conductive layer C3 and the pad conductive layer C21a may be manufactured in the same step and thus may be regarded as the same conductive layer. Next, the bonding elements CE3 are formed to bond the electronic units 240 to the pad conductive layer C21a, and then a second insulating layer I2 is formed on the third insulating layer 13. The second insulating layer I2 surrounds and covers the electronic units 240.

Next, as shown in FIG. 12, the holes TV21, the via conductive layer C21b and the pad conductive layer CP2 may be formed in sequence by repeating the above steps. The via conductive layer C21b and the pad conductive layer C21a together constitute the second conductive layer C21. In this embodiment, the second conductive layer C2 is exemplarily a single-layer structure including one layer of the second conductive layer C21, but not limited thereto.

Please refer to FIG. 13, bonding elements CE2 may be formed on the pad conductive layer CP2. The carrier 750 and the debonding layer 730 disposed thereon may be removed, and then the conductive structure 100d may be turned over to bond the electronic units 210 with the pad conductive layer CP1 through the bonding elements CE1. Next, an encapsulation layer 220d surrounding and covering the electronic unit 210 is formed. Next, a cutting process may be performed to cut the electronic device in FIG. 13 into two parts, and then external elements 300 are connected to the bonding elements CE2 of the two parts, so that two electronic devices 1d in FIG. 10 can be obtained. For other details of the method for manufacturing the electronic device 1d, references may be made to the relevant descriptions of the method for manufacturing the electronic devices 1a, 1b, and 1c, and are omitted herein.

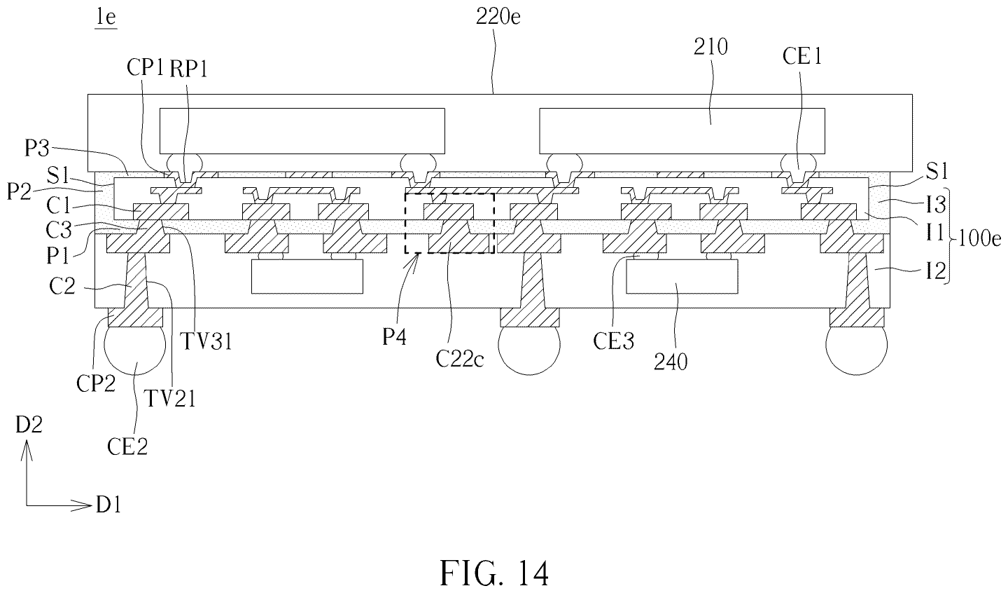

Please refer to FIG. 14, which is a schematic cross-sectional view showing an electronic device 1e according to yet another embodiment of the present disclosure. The electronic device 1e includes a circuit structure 100e, a plurality of electronic units 210, a plurality of electronic units 240, an encapsulation layer 220e, a plurality of bonding elements CE1, a plurality of bonding elements CE2, and a plurality of bonding elements CE3. Moreover, the electronic device 1e may optionally include a carrier (not shown) electrically connected to the plurality of bonding elements CE2. For details of the carrier, references may be made to the description of the external element 300 in FIG. 10. The electronic device 1e may be an integrated fan-out package unit.

The main difference between the electronic device 1e and the electronic device 1d is that the number of the electronic units 210 is two, and the number of the electronic units 240 is two. The two electronic units 210 are disposed on the circuit structure 100e. The two electronic units 210 are disposed at the same side (herein, the upper side) of the circuit structure 100e along the horizontal direction D1, and the two electronic units 210 may be arranged side by side along the horizontal direction D1. The encapsulation layer 220e surrounds the two electronic units 210. The aforementioned “the two electronic units 210 may be arranged side by side along the horizontal direction D1” may refer that the two electronic units 210 do not overlap in the vertical direction D2. The two electronic units 240 are disposed in the second insulating layer I2 of the circuit structure 100e. The second insulating layer I2 surrounds the electronic units 240. The two electronic units 240 are disposed at the same side (herein, the lower side) of the first insulating layer I1 along the horizontal direction D1, and the two electronic units 240 may be arranged side by side along the horizontal direction D1. The aforementioned “the two electronic units 240 may be arranged side by side along the horizontal direction D1” may refer that the two electronic units 240 do not overlap in the vertical direction D2.

The first conductive layer C1, the second conductive layer C2 and the third conductive layer C3 may be electrically connected to form wires in the vertical direction D2 and/or the horizontal direction D1, so that signals can be transmitted between the two electronic units 210 and the two electronic units 240 in the vertical direction D2 and/or the horizontal direction D1. In this embodiment, the circuit structure 100e may further include a heat dissipation layer for providing a heat dissipation function. As shown in FIG. 14, a portion of the first conductive layer C1, a portion of the second conductive layer C2, and a portion of the third conductive layer C3 are connected with each other to form a heat dissipation layer, as shown in the portion P4 circled by the dotted line in FIG. 14. For details of the heat dissipation layer, references may be made to the related description above, and are omitted herein.

The main difference between the manufacturing method of the electronic device 1e and the manufacturing method of the electronic device 1d is the pattern of the first conductive layer C1, the second conductive layer C2 and the third conductive layer C3, which may be realized by changing the configuration of the patterned photoresist. In addition, the method for manufacturing the electronic device 1e may omit the cutting process. The method for manufacturing the electronic device 1e may refer to the relevant description of the method for manufacturing the electronic devices 1a, 1b, 1c, and 1d, and are omitted herein.

In the electronic device according to the present disclosure, with the circuit structure including at least one first insulating layer and at least one second insulating layer with different levels of stiffness, and the at least one first insulating layer with less stiffness being disposed between the first electronic unit and the at least one second insulating layer, it is beneficial to improve both the input/output density and the supportability of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a circuit structure;
a first electronic unit disposed on the circuit structure; and
an encapsulation layer surrounding the first electronic unit;
wherein the circuit structure comprises at least one first insulating layer and at least one second insulating layer, the at least one first insulating layer is disposed between the first electronic unit and the at least one second insulating layer, and a stiffness of the at least one first insulating layer is less than a stiffness of the at least one second insulating layer.

2. The electronic device of claim 1, wherein the stiffness of the at least one first insulating layer is less than a stiffness of the encapsulation layer.

3. The electronic device of claim 1, wherein the encapsulation layer further surrounds the at least one first insulating layer.

4. The electronic device of claim 1, wherein the encapsulation layer extends into the at least one second insulating layer.

5. The electronic device of claim 1, wherein a thickness of the at least one first insulating layer is less than a thickness of the at least one second insulating layer.

6. The electronic device of claim 1, wherein the circuit structure further comprises:
at least one first conductive layer disposed in the at least one first insulating layer; and
at least one second conductive layer disposed in the at least one second insulating layer, wherein a thickness of the at least one first conductive layer is less than a thickness of the at least one second conductive layer.

7. The electronic device of claim 1, further comprising:
a plurality of first bonding elements disposed between the first electronic unit and the circuit structure.

8. The electronic device of claim 7, further comprising:
a plurality of second bonding elements disposed on a surface of the circuit structure away from the first electronic unit, wherein a size of at least one of the plurality of first bonding elements is less than a size of at least one of the plurality of second bonding elements.

9. The electronic device of claim 7, further comprising:
a filler disposed in a gap between two of the plurality of first bonding elements.

10. The electronic device of claim 9, wherein the encapsulation layer further surrounds the filler.

11. The electronic device of claim 1, further comprising:
an external element electrically connected to the circuit structure.

12. The electronic device of claim 1, wherein a coefficient of thermal expansion of the encapsulation layer is less than a coefficient of thermal expansion of the at least one first insulating layer, and the coefficient of thermal expansion of the encapsulation layer is less than a coefficient of thermal expansion of the at least one second insulating layer.

13. The electronic device of claim 1, wherein the circuit structure further comprises:
a heat dissipation layer disposed in the at least one first insulating layer and/or the at least one second insulating layer.

14. The electronic device of claim 1, further comprising:
a second electronic unit disposed in the at least one second insulating layer, wherein the second electronic unit and the first electronic unit are located at different side of the first insulating layer in a vertical direction.

15. The electronic device of claim 14, wherein the at least one second insulating layer surrounds the second electronic unit.

16. The electronic device of claim 1, further comprising:
a second electronic unit disposed on the circuit structure, wherein the second electronic unit and the first electronic unit are disposed at a same side of the circuit structure along a horizontal direction.

17. The electronic device of claim 16, wherein the encapsulation layer further surrounds the second electronic unit.

18. The electronic device of claim 1, further comprising:
at least one third insulating layer surrounding the at least one first insulating layer.

19. The electronic device of claim 18, wherein the stiffness of the at least one first insulating layer is less than a stiffness of the at least one third insulating layer.

20. The electronic device of claim 18, wherein the at least one third insulating layer comprises a first portion, a second portion and a third portion, the first portion is disposed at a side of the at least one first insulating layer away from the first electronic unit, the second portion surrounds the at least one first insulating layer, and the third portion is disposed between the at least one first insulating layer and the first electronic unit.
